(19) United States
(12) Patent Application Publication
(10) Pub. No.: US 2026/0052757 A1
(43) Pub. Date: Feb. 19, 2026

(54) CAPACITOR MODULE

(71) Applicant: Winbond Electronics Corp., Taichung City (TW)

(72) Inventors: San-Ha Park, Hsinchu (TW); Chih-Feng Lin, Hsinchu County (TW)

(73) Assignee: Winbond Electronics Corp., Taichung City (TW)

(21) Appl. No.: 19/260,618

(22) Filed: Jul. 7, 2025

Related U.S. Application Data
(60) Provisional application No. 63/682,342, filed on Aug. 13, 2024.

(51) Int. Cl. H10D 84/00; H01L 21/66; H01L 21/78; H01L 23/525; H01L 23/528

(52) U.S. Cl. CPC H10D 84/212; H01L 21/78; H01L 22/22; H01L 22/34; H01L 23/5256; H01L 23/528; H01L 23/5283

(57) ABSTRACT

A capacitor module includes a first die and a second die. Each of the first die and the second die includes a capacitor device and a circuit structure electrically connected to the capacitor device. The circuit structure includes a pad and a first signal line. The first signal line includes a first pad connection portion and a first signal transmission portion. The first pad connection portion is located below the pad and is electrically connected to the pad. The first signal transmission portion is electrically connected to the capacitor device. The first signal line of the first die further includes first fuses connecting the first pad connection portion and the first signal transmission portion. The first signal line of the second die is broken, so that the first pad connection portion of the second die is electrically separated from the first signal transmission portion.

### CROSS-REFERENCE TO RELATED APPLICATION

This application claims the priority benefit of U.S. provisional Ser. No. 63/682,342, filed on Aug. 13, 2024. The entirety of the above-mentioned patent application is hereby incorporated by reference herein and made a part of this specification.

### BACKGROUND

### Technical Field

The disclosure relates to a capacitor module.

### Description of Related Art

A silicon capacitor provides good energy storage and voltage stabilization functions and is capable of effectively suppressing noise in high-frequency circuits, so stability and efficient operation of a system is ensured. Therefore, silicon capacitors are often used in communication equipment, medical equipment, and automotive electronic systems.

However, when a silicon capacitor fails, it may lead to decreased circuit filtering performance and increased noise, and signal quality is thus affected. In addition, a damaged silicon capacitor may cause power instability, resulting in voltage fluctuations, overload, or even entire system failure. In applications with high reliability requirements, such as medical equipment or automotive electronics, silicon capacitor damage may also affect equipment safety and long-term operation. Therefore, the yield of silicon capacitors is crucial for ensuring the overall performance and reliability of electronic components.

### SUMMARY

The disclosure provides a capacitor module featuring the advantages of high yield and low leakage.

At least one embodiment of the disclosure provides a capacitor module including a first die and a second die. Each of the first die and the second die includes a capacitor device and a circuit structure electrically connected to the capacitor device. The circuit structure includes a pad and a first signal line. The first signal line includes a first pad connection portion and a first signal transmission portion. The first pad connection portion is located below the pad and is electrically connected to the pad. The first signal transmission portion is electrically connected to the capacitor device. The first signal line of the first die further includes first fuses connecting the first pad connection portion and the first signal transmission portion. The first signal line of the second die is broken, so that the first pad connection portion of the second die is electrically separated from the first signal transmission portion.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic three-dimensional view of a wafer according to an embodiment of the disclosure.

FIG. 2A is a schematic top view of a capacitor module according to an embodiment of the disclosure. FIG. 2B is a schematic cross-sectional view taken along a line A-A′ of FIG. 2A.

FIG. 3 is a schematic top view of a die according to an embodiment of the disclosure.

FIG. 4A is a schematic local top view of the die according to an embodiment of the disclosure. FIG. 4B is a schematic cross-sectional view taken along a line A-A′ of FIG. 4A.

FIG. 5A is a schematic top view of the capacitor module according to an embodiment of the disclosure. FIG. 5B is a schematic top view of a second die in FIG. 5A.

FIG. 6A is a schematic local top view of the die according to an embodiment of the disclosure. FIG. 6B is a schematic cross-sectional view taken along a line A-A′ of FIG. 6A.

FIG. 7 is a schematic local top view of the die according to another embodiment of the disclosure.

FIG. 8A is a schematic local top view of the die according to still another embodiment of the disclosure. FIG. 8B is a schematic cross-sectional view taken along a line A-A′ of FIG. 8A. FIG. 8C is a schematic cross-sectional view taken long a line B-B′ of FIG. 8A.

FIG. 9A is a schematic local top view of the die according to still another embodiment of the disclosure. FIG. 9B is a schematic cross-sectional view taken along a line A-A′ of FIG. 9A. FIG. 9C is a schematic cross-sectional view taken along a line B-B′ of FIG. 9A.

FIG. 10 is a schematic local cross-sectional view of the die according to yet another embodiment of the disclosure.

FIG. 11 is a flow chart of a method for repairing a capacitor module according to an embodiment of the disclosure.

### DESCRIPTION OF THE EMBODIMENTS

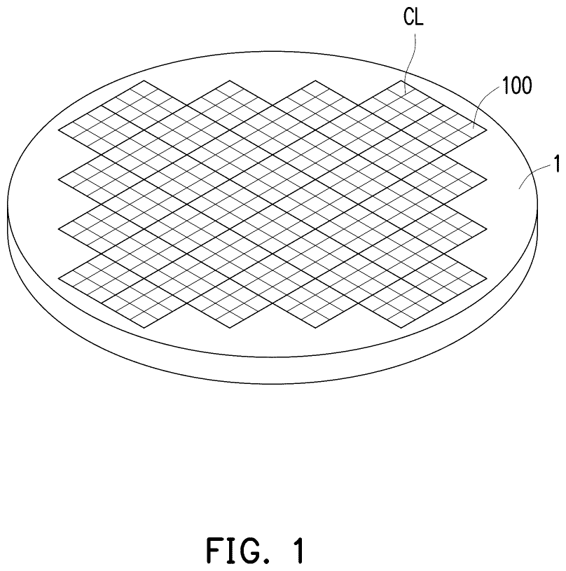

FIG. 1 is a schematic three-dimensional view of a wafer 1 according to an embodiment of the disclosure. The wafer 1 includes a plurality of dies 100, and a cutting lane CL is provided between two dies 100.

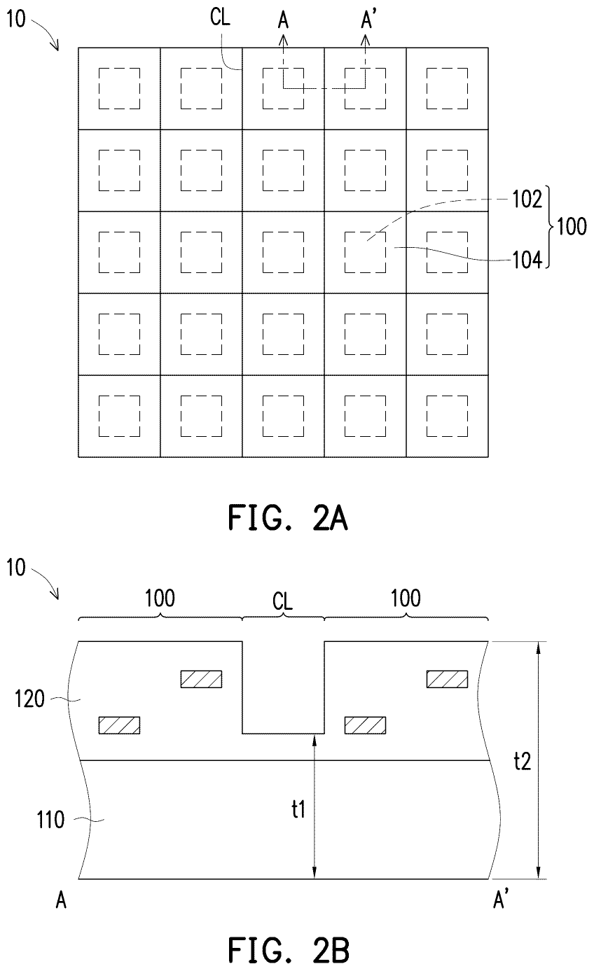

FIG. 2A is a schematic top view of a capacitor module according to an embodiment of the disclosure. FIG. 2B is a schematic cross-sectional view taken along a line A-A′ of FIG. 2A. Referring to FIG. 2A and FIG. 2B, the wafer 1 is cut to obtain a capacitor module 10 including the plurality of dies 100. The number of dies 100 in the capacitor module 10 may be determined according to actual needs. For instance, each die 100 includes a component region 102 and a peripheral region 104 surrounding the component region 102. The component region 102 includes a capacitor device (not shown in FIG. 2A). For instance, the capacitor device includes a plurality of capacitors connected in parallel, where the capacitors may be silicon capacitors, metal-insulation layer-metal capacitors, or any other type of capacitors. The quantity of the dies 100 in the capacitor module 10 is determined based on the capacitance requirements. When more capacitor devices are needed, the number of the dies 100 in the capacitor module 10 increases.

In an embodiment, each die 100 includes a substrate 110 and a circuit structure 120 located on the substrate 110. The substrate 110 may be a semiconductor substrate. The circuit structure 120 may be, for example, an interconnect layer or a redistribution layer. In an embodiment, the capacitor device is located in the substrate 110 and/or the circuit structure 120.

The cutting lane CL is located in the peripheral region 104. In an embodiment, a thickness t1 of the capacitor module 10 at the cutting lane CL is less than a thickness t2 of the capacitor module 10 at the component region 102.

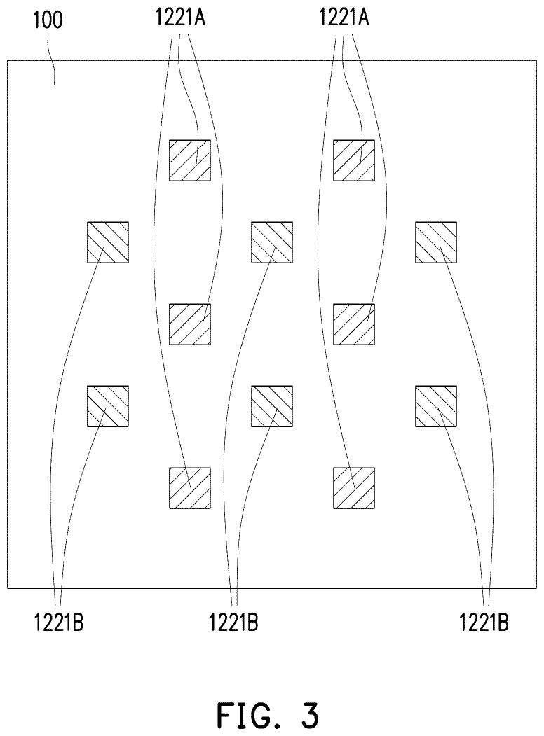

FIG. 3 is a schematic top view of a die 100 according to an embodiment of the disclosure. Specifically, FIG. 3 is a schematic top view of the circuit structure 120 of each die 100 in FIG. 2A. Referring to FIG. 3, the circuit structure 120 of the die 100 includes a plurality of pads 1221A and a plurality of pads 1221B. Each pad 1221A and each pad 1221B are electrically connected to opposite electrodes of a capacitor. For instance, the pad 1221A is configured to receive a power voltage from a power supply, while the pad 1221B is configured to receive a ground voltage. In an embodiment, the pads 1221A and the pads 1221B may have similar structures.

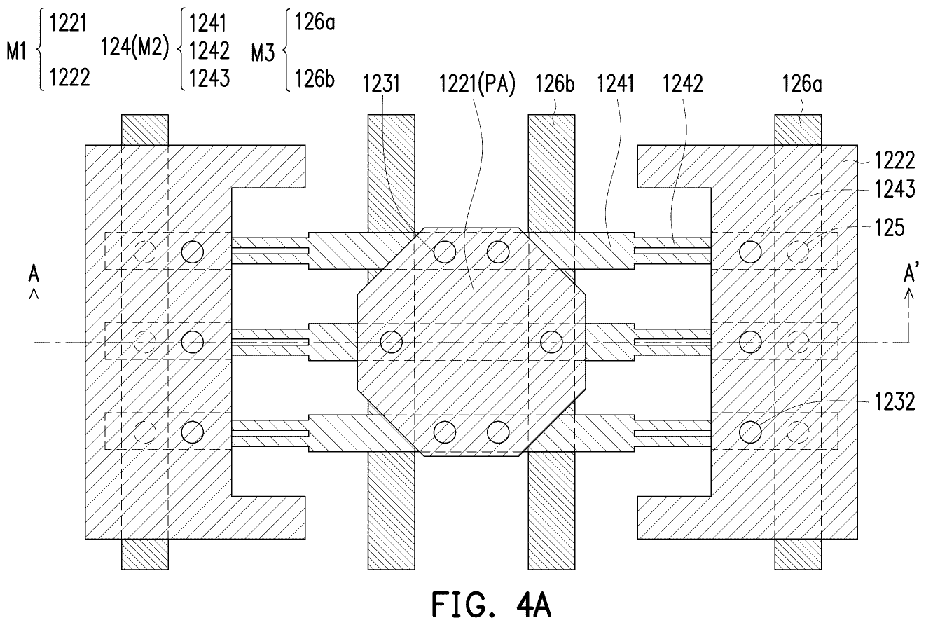

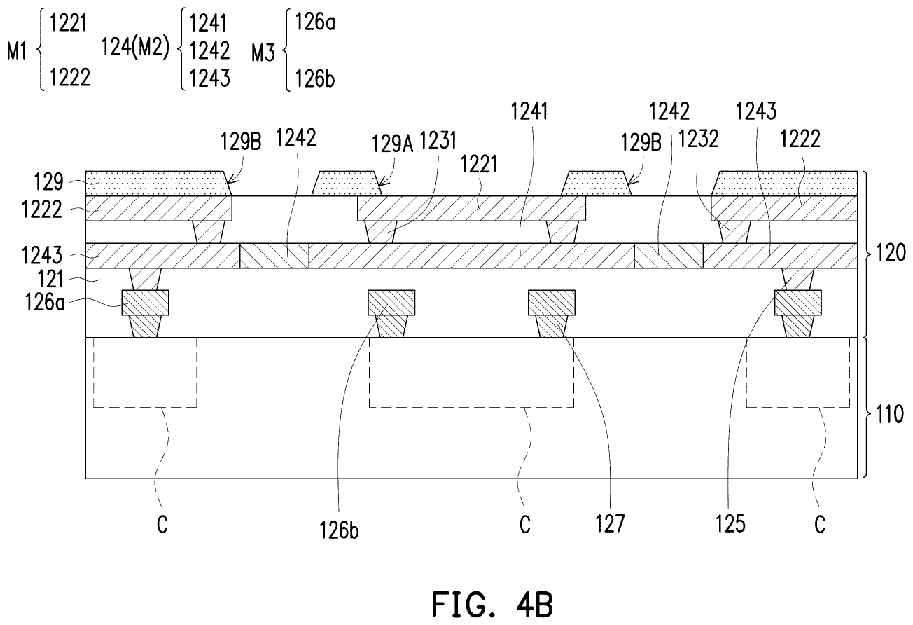

FIG. 4A is a schematic local top view of the die according to an embodiment of the disclosure. For instance, FIG. 4A is a schematic local top view of the die 100 in FIG. 3. The structure of the pads 1221A and/or the pads 1221B in FIG. 3 may be as shown by a pad 1221 in FIG. 4A. FIG. 4B is a schematic cross-sectional view taken along a line A-A′ of FIG. 4A.

Referring to FIG. 4A and FIG. 4B, a capacitor device C is located in or on the substrate 110. The circuit structure 120 is located on the substrate 110 and is electrically connected to the capacitor device C. The circuit structure 120 includes the pad 1221, an electrode layer 1222, a via 1231, a via 1232, a signal line 124, a via 125, a transmission line 126a, a transmission line 126b, a via 127, an insulation structure 121, and a protection layer 129.

The pad 1221 is disposed in a bonding region PA. The electrode layer 1222 surrounds the pad 1221, and the electrode layer 1222 is separated from the pad 1221. In an embodiment, the pad 1221 and the electrode layer 1222 belong to a same conductive layer (e.g., a conductive layer M1). For instance, the pad 1221 and the electrode layer 1222 are formed together. In an embodiment, a shape of the pad 1221 may include an octagon, a hexagon, a rectangle, a triangle, a circle, or other geometric shapes.

The signal line 124 includes a pad connection portion 1241, a signal transmission portion 1243, and fuses 1242 connecting the pad connection portion 1241 and the signal transmission portion 1243. In an embodiment, the pad connection portion 1241 is located below the pad 1221, while the signal transmission portion 1243 is located below the electrode layer 1222. The pad connection portion 1241 is electrically connected to the pad 1221. For instance, the pad 1221 is electrically connected to the pad connection portion 1241 through the via 1231 located below it. The signal transmission portion 1243 may optionally be electrically connected to the electrode layer 1222. For instance, the electrode layer 1222 is electrically connected to the signal transmission portion 1243 through the via 1232 located below it.

The fuses 1242 overlap a gap between the electrode layer 1222 and the pad 1221. When a die failure (e.g., leakage) occurs, the fuses 1242 may be cut off by laser or an etching process, so that the pad connection portion 1241 and the signal transmission portion 1243 are electrically separated from each other, and that the negative impact of the failed die on the capacitor module is reduced. In an embodiment, each fuse corresponding to each pad 1221A (refer to FIG. 3) and/or each pad 1221B (refer to FIG. 3) of the failed die is cut off, so that the failed die is electrically separated from other dies in the capacitor module. Although the total capacitance value of the capacitor module is lowered, it can also avoid the negative impact of the failed die on other normally functioning dies (e.g., reducing the problem caused by leakage). Therefore, the yield of the capacitor module may be improved.

A width of each fuse 1242 is less than a width of the pad connection portion 1241 and a width of the signal transmission portion 1243, making the fuse 1242 easier to be cut off. However, due to the narrower width of each fuse 1242, the fuse 1242 may cause an increase in the overall resistance value of the signal line 124. Compared to the use of only one fuse 1242 to connect the pad connection portion 1241 and the signal transmission portion 1243, the arrangement of plural fuses 1242 between one pad connection portion 1241 and one signal transmission portion 1243 may lower the resistance value of the signal line 124. The number of the fuses 1242 between one pad connection portion 1241 and one signal transmission portion 1243 may be adjusted according to actual needs.

In this embodiment, a plurality of signal lines 124 belong to a same conductive layer (e.g., a conductive layer M2). For instance, plural signal lines 124 are formed together. The conductive layer M2 is electrically connected to the conductive layer M1 through the via 1231 and the via 1232.

The transmission line 126a and the transmission line 126b are located below the signal line 124, where the transmission line 126a is located below the signal transmission portion 1243, and the transmission line 126b is located below the pad connection portion 1241. The transmission line 126a and the transmission line 126b are located between the signal line 124 and the capacitor device C, where the signal transmission portion 1243 is electrically connected to the transmission line 126a through the via 125 and is electrically connected to the capacitor device C through the transmission line 126a and the corresponding via 127 below the transmission line 126a. On the other hand, the transmission line 126b is electrically connected to the capacitor device C through the corresponding via 127. However, the transmission line 126b is not electrically connected to the pad 1221 shown in FIG. 4A and FIG. 4B. Specifically, a lower surface of the pad connection portion 1241 is not directly connected to any via, making it impossible for the pad connection portion 1241 to be electrically connected to the transmission line 126b directly below it through a via. In this embodiment, the insulation structure 121 covers the signal line 124, and the entire lower surface of the pad connection portion 1241 contacts the insulation structure 121. In an embodiment, the transmission line 126b may be electrically connected to other pads not shown in FIG. 4A and FIG. 4B.

In an embodiment, an extending direction of the transmission lines 126a and 126b is not parallel to an extending direction of the signal line 124. For instance, the extending direction of the transmission lines 126a and 126b is perpendicular to the extending direction of the signal line 124.

In this embodiment, the plural transmission lines 126a and 126b belong to a same conductive layer (e.g., a conductive layer M3). For instance, the transmission lines 126a and 126b are formed together. The conductive layer M3 is electrically connected to the conductive layer M2 through the via 125.

The protection layer 129 is located on the insulation structure 121 and has an opening 129A and an opening 129B. The opening 129A exposes the pad 1221, for example, exposing the pad 1221 in the bonding region PA. The opening 129B overlaps the fuses 1242. In an embodiment, positions of the fuses 1242 may be identified by means of a position of the opening 129B.

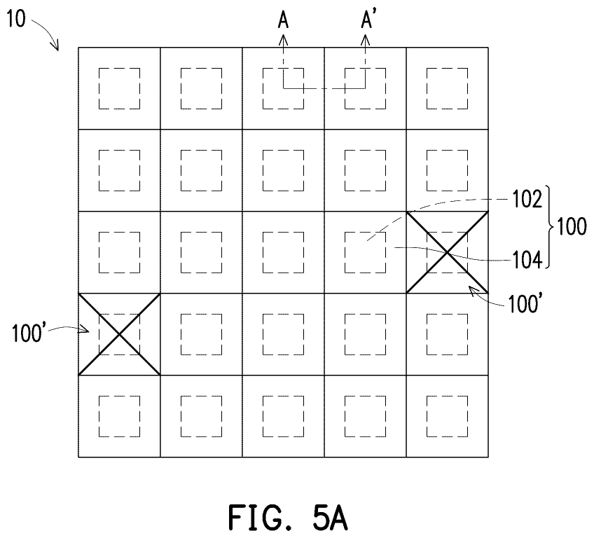

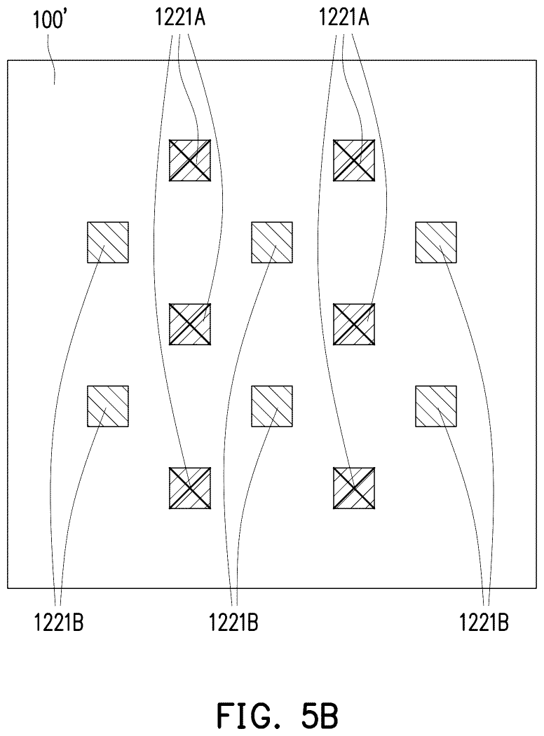

Each die 100 in the capacitor module 10 shown in FIG. 2A is tested. For instance, a probe is used to contact the pad 1221A (refer to FIG. 3) and the pad 1221B (refer to FIG. 3), and a leakage current is detected. The total leakage current of the capacitor module 10 is calculated. Based on a total leakage amount, it is calculated how many fuses 1242 in the die 100 need to be cut off. For instance, after each die 100 in the capacitor module 10 is tested, it is found that some of the dies 100 have failed, as shown in FIG. 5A. The failed dies are marked as dies 100′and are indicated with cross symbols in the figure. In an embodiment, each normally functioning die 100 may be referred to as a first die, while each failed die 100′may be referred to as a second die. Between the die 100 and the die 100′, the cutting lane CL is provided, and the substrate of the die 100 (the substrate 110 shown in FIG. 2B or FIG. 4B) is connected to the substrate of the die 100′ (the substrate 110 shown in FIG. 2B or FIG. 4B).

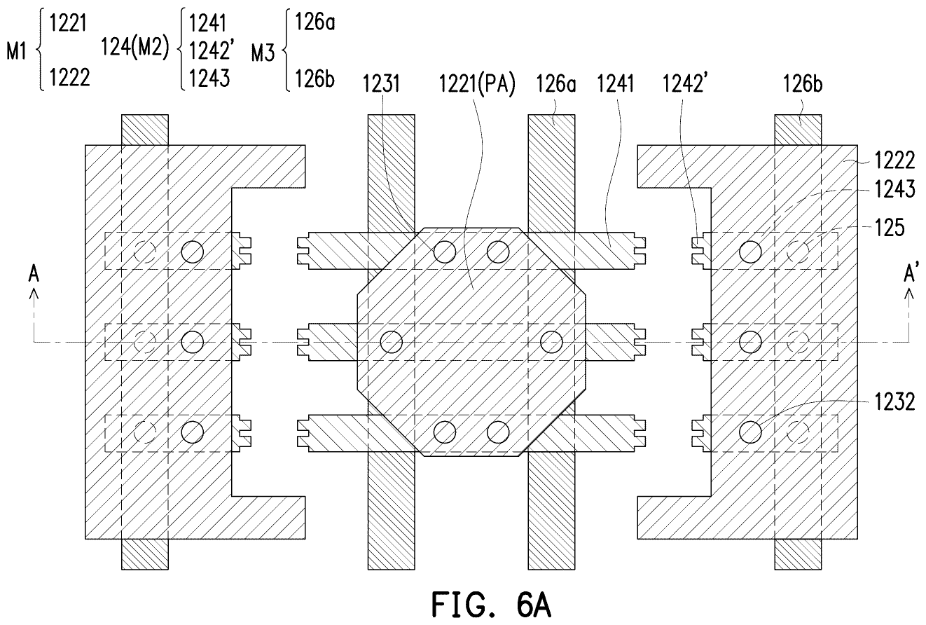

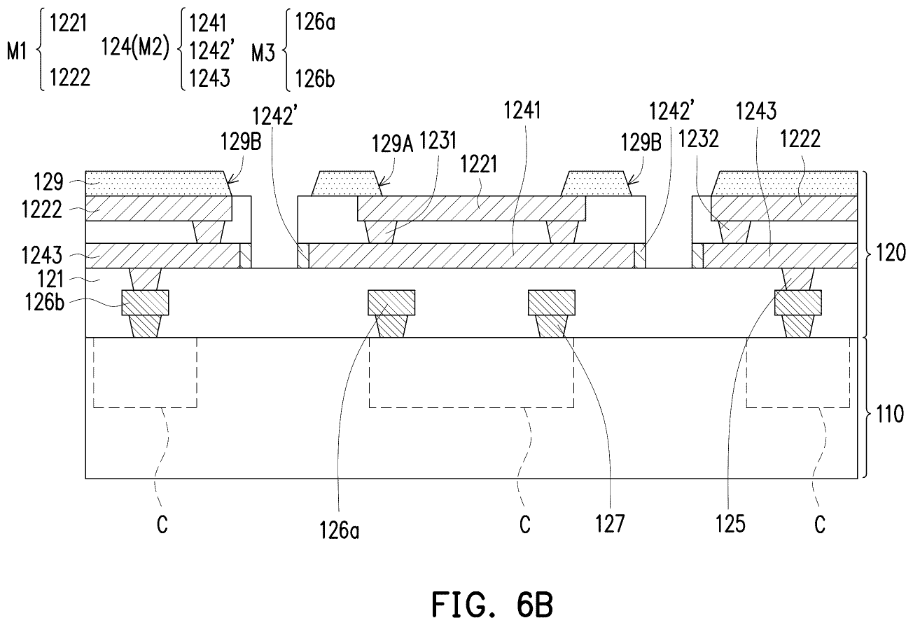

The circuit structure of each of the die 100 and the die 100′includes multiple signal lines 124. The signal lines 124 of the die 100 include multiple fuses 1242 connecting the pad connection portion 1241 and the signal transmission portion 1243, as shown in FIG. 4A and FIG. 4B. However, the signal lines 124 of the die 100′are broken, such that the pad connection portion 1241 of the die 100′is electrically separated from the signal transmission portion 1243. For instance, the fuses 1242 are cut off by means of laser or an etching process, as shown in FIG. 6A and FIG. 6B. Specifically, a portion of the insulation structure 121 and the fuses 1242 below the opening 129B are removed by means of laser or an etching process, causing the fuses 1242 below the opening 129B to be broken. In an embodiment, the opening 129B of the die 100 overlaps the fuses 1242, as shown in FIG. 4B. However, the opening 129B of the die 100′overlaps the position where the signal lines 124 of die 100′are broken, that is, the position where the fuses 1242 are broken.

By cutting off the signal lines 124 of the die 100′, the capacitor device C of the die 100′is electrically separated from the pad 1221 originally connected to it. In an embodiment, each pad 1221A of the die 100′is cut off in the manner shown in FIG. 6A and FIG. 6B, while the pad 1221B maintains the original condition without the fuses 1242 being cut off, as shown in FIG. 5B. In other embodiments, each pad 1221B of the die 100′may be cut off in the manner shown in FIG. 6A and FIG. 6B, while the pad 1221A maintains the original condition without the fuses being cut off. In other embodiments, each pad 1221A and each pad 1221B of the die 100′are all cut off in the manner shown in FIG. 6A and FIG. 6B.

In an embodiment, after the fuses 1242 are cut off, residues 1242′remain on the pad connection portion 1241 and/or the signal transmission portion 1243.

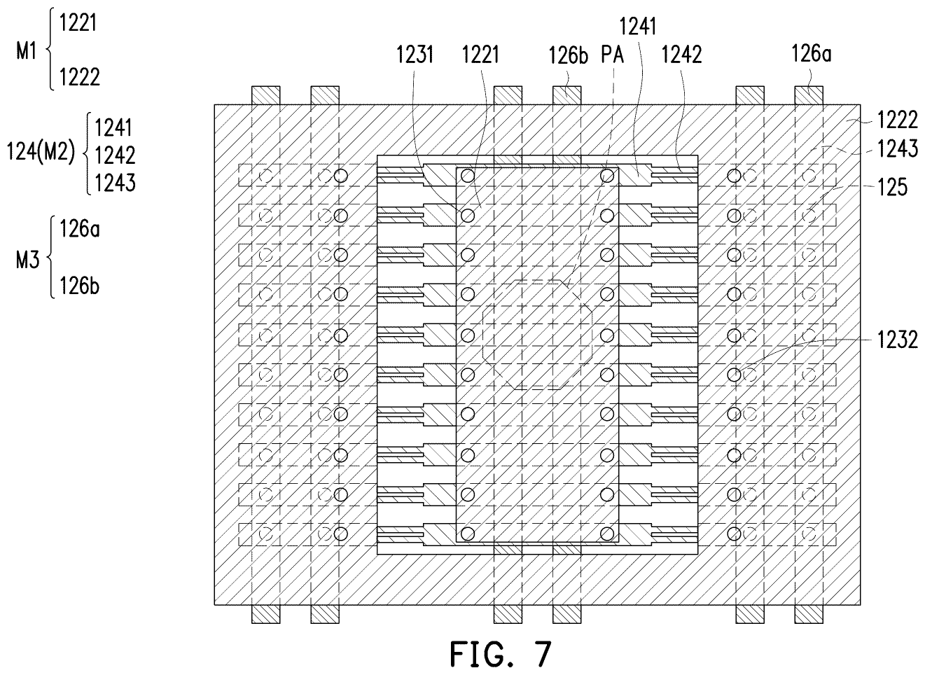

FIG. 7 is a schematic local top view of the die according to another embodiment of the disclosure. For instance, FIG. 7 is a schematic local top view of the die 100 of FIG. 3. The structure of the pads 1221A and/or the pads 1221B in FIG. 3 may be as shown by the pad 1221 in FIG. 7. It should be noted that the reference numbers and some content provided in the embodiment shown in FIG. 4A and FIG. 4B are applied in the embodiments shown in FIG. 7, where the same or similar reference numbers serve to denote the same or similar elements, and the description of the same technical content is omitted and is not repeated herein.

Referring to FIG. 7, in this embodiment, reducing the width of the fuses 1242 may lead to an increase in the resistance value of the signal lines 124. To reduce the resistance between the pad 1221 and the capacitor device, increasing a length of the pad 1221 may allow one pad 1221 to be electrically connected to more signal lines 124.

In an embodiment, cutting off the fuses 1242 separates the pad 1221 from the capacitor device C. For instance, after testing and identifying a die as a failed die (or referred to as the second die), the fuses 1242 in the failed die are cut off to prevent the failed die from negatively affecting other dies.

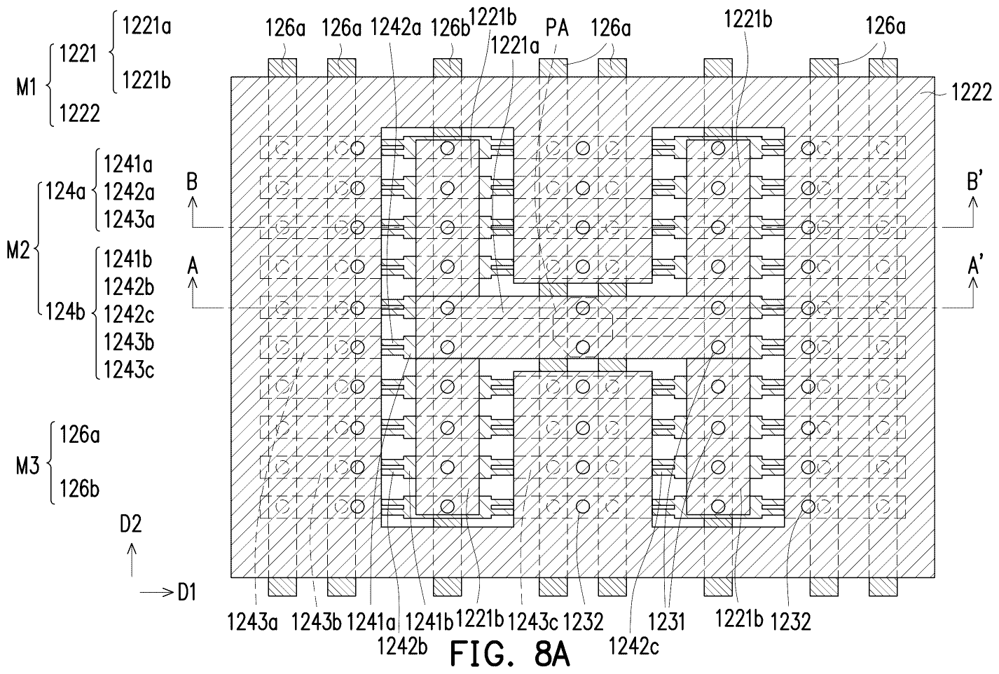

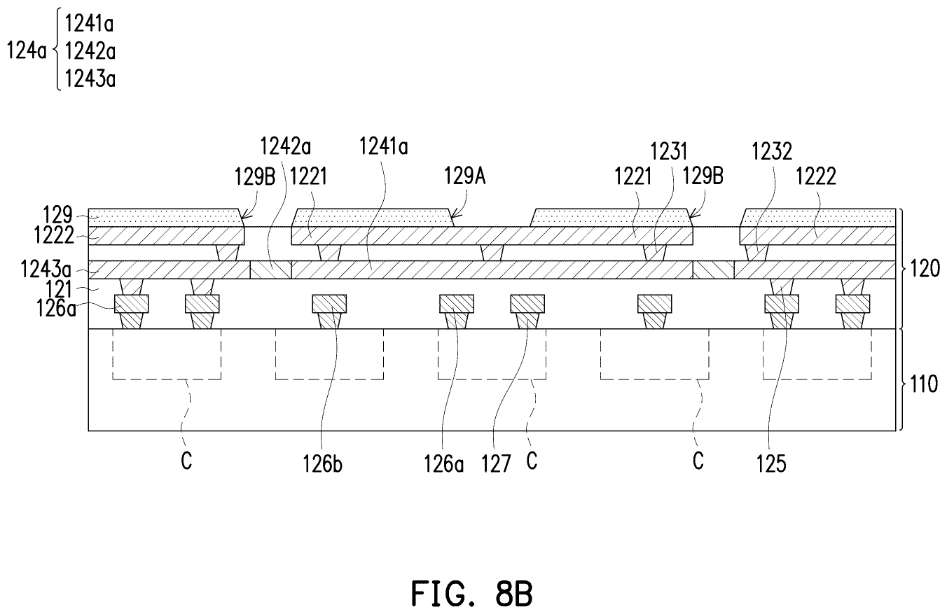

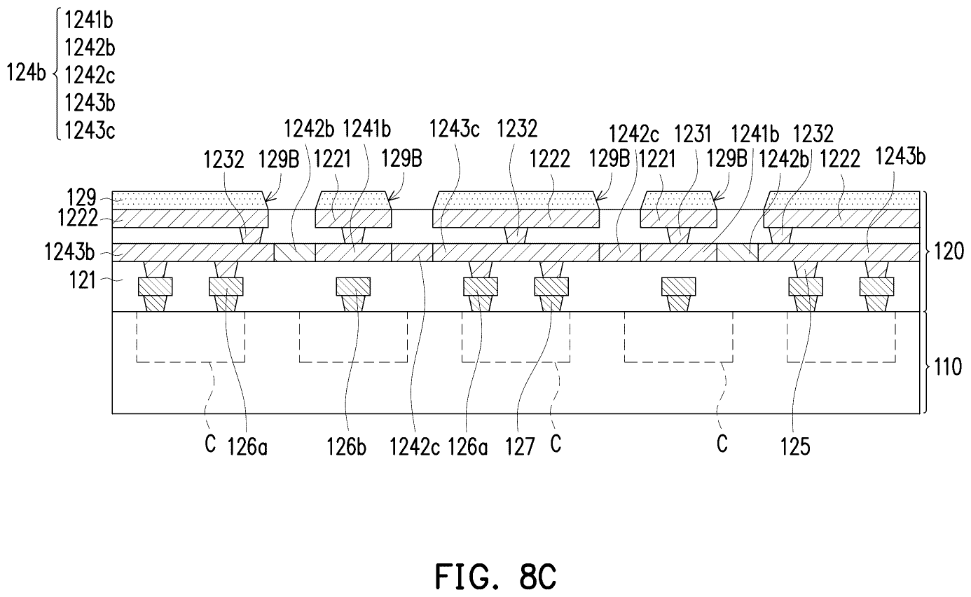

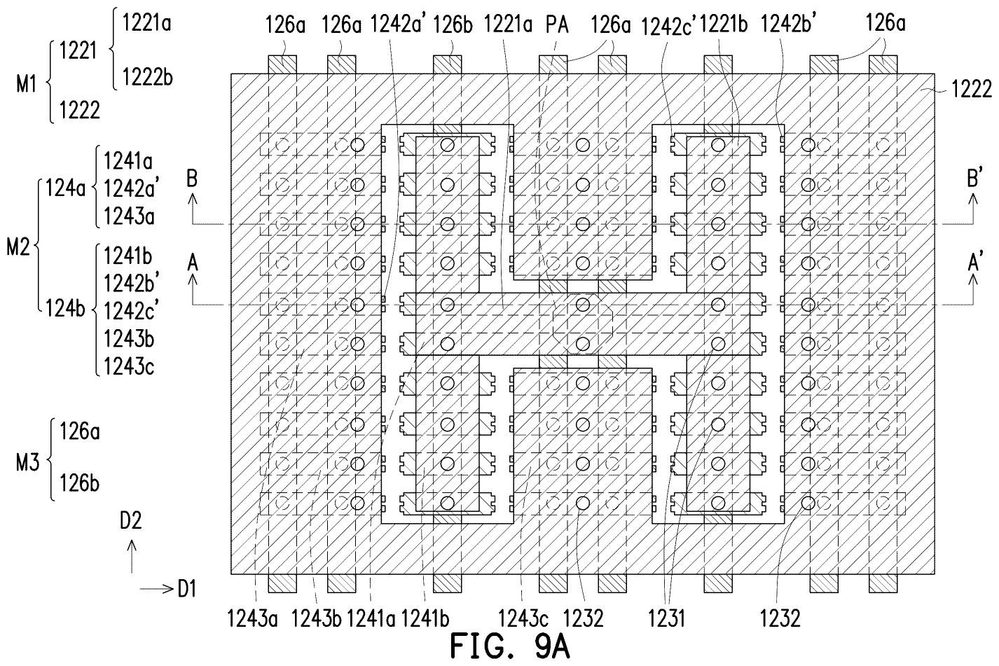

FIG. 8A is a schematic local top view of the die according to still another embodiment of the disclosure. FIG. 8B is a schematic cross-sectional view taken along a line A-A′ of FIG. 8A. FIG. 8C is a schematic cross-sectional view taken long a line B-B′ of FIG. 8A. For instance, FIG. 8A is a schematic local top view of the die 100 of FIG. 3. The structure of the pads 1221A and/or the pads 1221B in FIG. 3 may be as shown by the pad 1221 in FIG. 8A. It should be mentioned herein that the reference numerals and part of the content provided in the embodiments shown in FIG. 4A and FIG. 4B are applied in the embodiments shown in FIG. 8A to FIG. 8C, where the same or similar reference numerals serve to denote the same or similar components, and the description of the same technical content is omitted and is not repeated herein.

Referring to FIG. 8A to FIG. 8C, in this embodiment, the pad 1221 has, for example, an H shape. Specifically, the pad 1221 includes a main body portion 1221a and four branch portions 1221b. The main body portion 1221a extends in a direction D1. The branch portions 1221b are parallel to a direction D2. Two of the four branch portions 1221b extend outward from one side of the main body portion 1221a, while the other two extend outward from another side of the main body portion 1221a. The electrode layer 1222 surrounds the pad 1221.

Referring to FIG. 8A and FIG. 8B, the signal line 124a includes a pad connection portion 1241a, a signal transmission portion 1243a, and fuses 1242a connecting the pad connection portion 1241a and the signal transmission portion 1243a. The pad connection portion 1241a is located below the main body portion 1221a, and the main body portion 1221a is electrically connected to the pad connection portion 1241a through the via 1231. In this embodiment, a portion of the transmission line 126a extends through the pad connection portion 1241a of the signal line 124a below the main body portion 1221a, but there is no via connected to a bottom surface of the signal line 124a directly beneath the pad connection portion 1241a.

Referring to FIG. 8A and FIG. 8C, the signal line 124b includes a pad connection portion 1241b, a signal transmission portion 1243b, a signal transmission portion 1243c, a fuse 1242b, and a fuse 1242c. The signal line 124b is, for example, parallel to the signal line 124a. In this embodiment, the signal line 124a and the signal line 124b belong to the same conductive layer (i.e., the conductive layer M2). That is, the signal line 124a and the signal line 124b are formed together.

The pad connection portions 1241b of each signal line 124b are located below two of the four branch portions 1221b. The pad connection portions 1241b are electrically connected to the branch portion 1221b of the pad 1221 through via 1231.

The signal transmission portion 1243b and the signal transmission portion 1243c are located below the electrode layer 1222 and are electrically connected to the electrode layer 1222 through the via 1232. The signal transmission portion 1243b and the signal transmission portion 1243c are electrically connected to the capacitor device C. For instance, the signal transmission portion 1243b and the signal transmission portion 1243c are electrically connected to the capacitor device C through the via 125, the transmission line 126a, and the via 127. By means of the arrangement of the signal transmission portion 1243b and the signal transmission portion 1243c, the number of connection points between the conductive layer M1 and the conductive layer M2 may be increased (e.g., increasing the number of vias 1232), so that the resistance value is lowered.

The fuses 1242b connect the pad connection portion 1241b and the signal transmission portion 1243b. The fuses 1242c connect the pad connection portion 1241b and the signal transmission portion 1243c. The numbers of the fuses 1242b and the fuses 1242c may be adjusted according to actual needs.

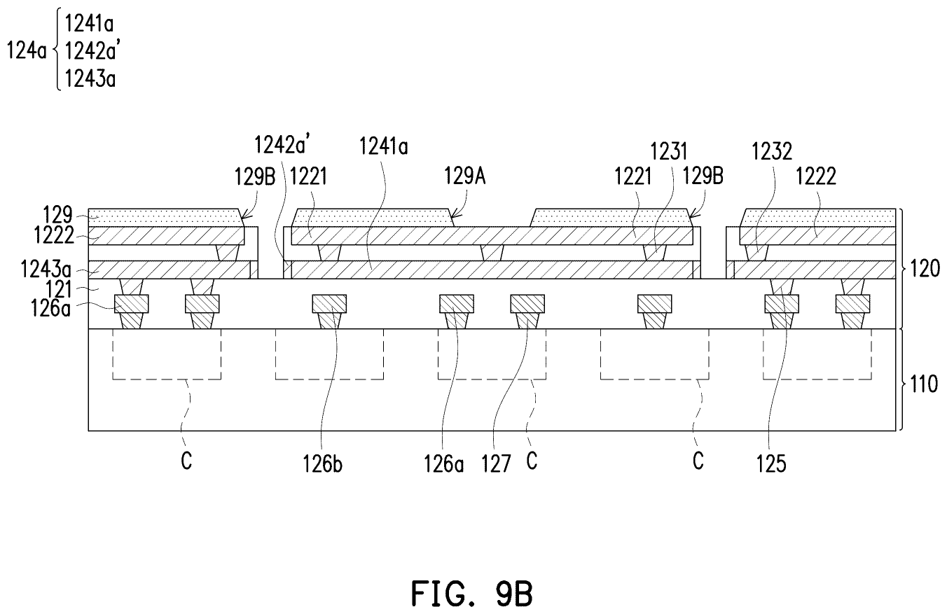

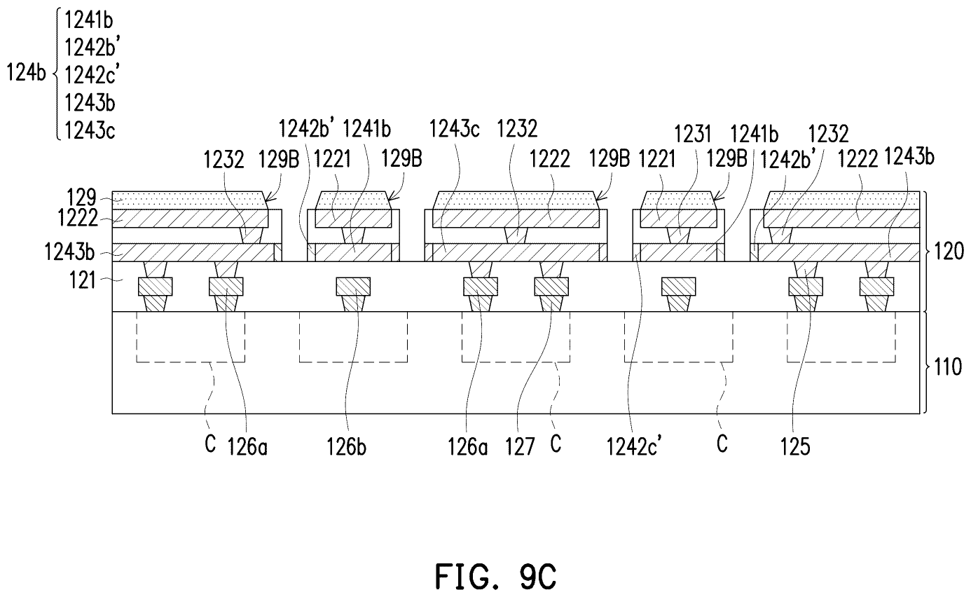

In an embodiment, each die in the capacitor module is tested, and next, the fuses 1242a, the fuses 1242b, and the fuses 1242c in the failed die (or referred to as the second die) are cut off, as shown in FIG. 9A, FIG. 9B, and FIG. 9C, by means of laser or and etching process, for example. Therefore, in the repaired capacitor module, in the normal die (or referred to as the first die), the pad 1221 (e.g., the pad 1221A or the pad 1221B in FIG. 5B) is electrically connected to the capacitor device C. In the failed die, the pad 1221 (e.g., the pad 1221A or the pad 1221B in FIG. 5B) is electrically separated from the capacitor device C. The signal line 124a of the failed die is broken, so that the pad connection portion 1241a is electrically separated from the signal transmission portion 1243a, as shown in FIG. 9A and FIG. 9B. The signal line 124b of the failed die is broken, so that the pad connection portion 1241b is electrically separated from the signal transmission portion 1243b and the signal transmission portion 1243c, as shown in FIG. 9A and FIG. 9C.

In an embodiment, after the fuses 1242a, the fuses 1242b, and the fuses 1242c are cut off, residues 1242a′, 1242b′, and 1242c′ remain.

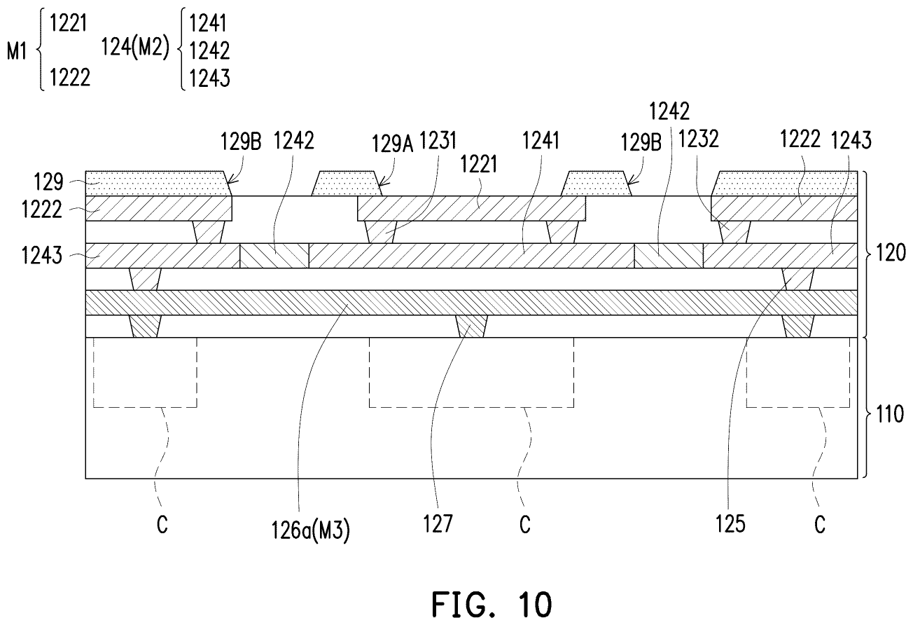

FIG. 10 is a schematic local cross-sectional view of the die according to yet another embodiment of the disclosure. It should be mentioned herein that the reference numerals and part of the content provided in the embodiments shown in FIG. 4A and FIG. 4B are applied in the embodiments shown in FIG. 10, where the same or similar reference numerals serve to denote the same or similar components, and the description of the same technical content is omitted. For the description of the omitted parts, please refer to the previous embodiments, and the description is not repeated herein. In the die of FIG. 10, a portion of the capacitor device C is located directly below the pad 1221, but the capacitor device C must be electrically connected to the pad 1221 through the fuse 1242. In other words, cutting off the fuse 1242 can electrically separate the pad 1221 from the capacitor device C.

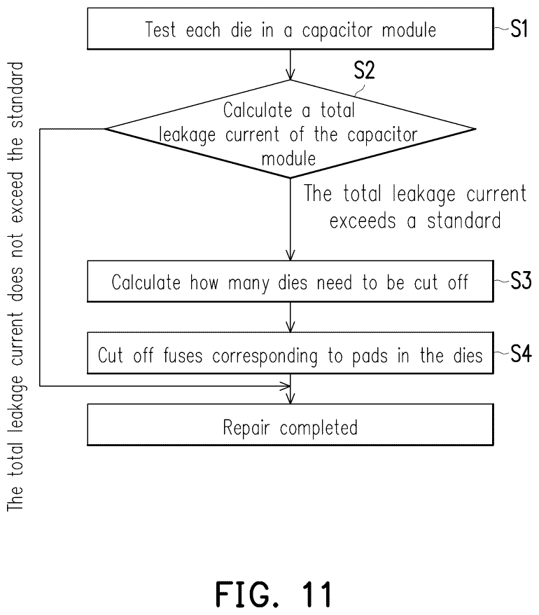

FIG. 11 is a flow chart of a method for repairing a capacitor module according to an embodiment of the disclosure. Referring to FIG. 10, in step S1, each die in a capacitor module is tested. For instance, each die 100 in the capacitor module 10 as shown in FIG. 3 is tested. After testing, some dies 100 are found to be failed dies 100′, as shown in FIG. 5A. The failed dies 100′ may have leakage problems, for example.

In step S2, the total leakage current of the capacitor module is calculated. In an embodiment, if the total leakage current exceeds a product standard, then proceed to step S3. If the total leakage current does not exceed the product standard, the repair is completed.

In step S3, based on the total leakage current, it is calculated how many dies need to be cut off.

Next, in step S4, the fuses corresponding to the pads in the dies are cut off. Specifically, laser or an etching process are used to cut off the pads and corresponding fuses in the failed dies, as shown in FIG. 6A, FIG. 6B, FIG. 9A, and FIG. 9B. In an embodiment, in addition to cutting off the fuses corresponding to the pads in the failed dies, the fuses corresponding to the pads in the non-failed dies may be cut off according to need, so that the total capacitance of the capacitor module may thus be adjusted.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A capacitor module, comprising:
a first die and a second die, wherein each of the first die and the second die comprises:
a capacitor device; and
a circuit structure electrically connected to the capacitor device and comprises:
a pad; and
a first signal line, comprising:
a first pad connection portion located below the pad and electrically connected to the pad; and
a first signal transmission portion electrically connected to the capacitor device, wherein the first signal line of the first die further comprises a plurality of first fuses connecting the first pad connection portion and the first signal transmission portion, and the first signal line of the second die is broken, so that the first pad connection portion of the second die is electrically separated from the first signal transmission portion.

2. The capacitor module according to claim 1, wherein the circuit structure of each of the first die and the second die further comprises:
an insulation structure covering the first signal line, and an entire lower surface of the first pad connection portion contacts the insulation structure.

3. The capacitor module according to claim 2, wherein the circuit structure of each of the first die and the second die further comprises:
a protection layer located on the insulation structure and having a first opening and a second opening, wherein the first opening exposes the pad, wherein the second opening of the first die overlaps the plurality of first fuses of the first die, and the second opening of the second die overlaps a position where the first signal transmission portion of the second die is broken.

4. The capacitor module according to claim 1, wherein the pad of each of the first die and the second die further comprises:
a main body portion extending in a first direction, wherein the first pad connection portion is located below the main body portion and electrically connected to the main body portion; and
four branch portions, wherein two of the four branch portions extend outward from one side of the main body portion, and the other two of the four branch portions extend outward from another side of the main body portion.

5. The capacitor module according to claim 4, wherein the circuit structure of each of the first die and the second die further comprises:
an electrode layer surrounding the pad; and
a second signal line parallel to the first signal line and comprising:
a plurality of second pad connection portions located below the two of the four branch portions and electrically connected to the pad;
a plurality of second signal transmission portions electrically connected to the capacitor device; and
a third signal transmission portion located below the electrode layer and electrically connected to the electrode layer, wherein the second signal line of the first die further comprises a plurality of second fuses connecting the second pad connection portions and the second signal transmission portions and a plurality of third fuses connecting the second pad connection portions and the third signal transmission portion, and the second signal line of the second die is broken, such that the second pad connection portions of the second die are electrically separated from the second signal transmission portions and the third signal transmission portion.

6. The capacitor module according to claim 1, wherein a width of each of the first fuses of the first die is less than a width of the first signal transmission portion.

7. The capacitor module according to claim 1, wherein the circuit structure of each of the first die and the second die further comprises:
a transmission line located between the first signal line and the capacitor device, wherein an extending direction of the transmission line is not parallel to an extending direction of the first signal line.

8. The capacitor module according to claim 1, wherein the second die is tested to be a failure die.

9. The capacitor module according to claim 1, wherein a cutting lane is provided between the first die and the second die, and a substrate of the first die is connected to a substrate of the second die.

10. The capacitor module according to claim 1, wherein the capacitor device of the first die comprises a plurality of capacitors connected in parallel.
